(19) United States
(12) Patent Application Publication
(10) Pub. No.: US 2016/0268279 A1
(43) Pub. Date: Sep. 15, 2016

(54) SEMICONDUCTOR MEMORY DEVICE

(71) Applicant: KABUSHIKI KAISHA TOSHIBA, Minato-ku (JP)

(72) Inventors: Yasuhiro UCHIYAMA, Yokkaichi (JP); Masaru KITO, Kuwana (JP)

(73) Assignee: KABUSHIKI KAISHA TOSHIBA, Minato-ku (JP)

(21) Appl. No.: 14/970,876

(22) Filed: Dec. 16, 2015

Related U.S. Application Data
(60) Provisional application No. 62/132,303, filed on Mar. 12, 2015.

(51) Int. Cl. H01L 27/115

(52) U.S. Cl. CPC H01L 27/11556; H01L 27/11582; H01L 27/1157

(57) ABSTRACT

A semiconductor memory device includes a plurality of memory blocks provided in a first direction. Each memory block includes a substrate, a plurality of conductive layers stacked on the substrate at a certain distance, and a plurality of semiconductor layers opposed to the conductive layers via an insulating layer and a charge accumulation layer. The semiconductor layers have a longitudinal direction in a direction perpendicular to the substrate. The conductive layers and the semiconductor layers are provided in the first direction. The distance between two memory blocks adjacent in the first direction is larger than the distance between the conductive layers adjacent in the first direction in each memory block.

### CROSS REFERENCE TO RELATED APPLICATIONS

This application is based on and claims the benefit of priority from prior U.S. Provisional Patent Application No. 62/132,303, filed on Mar. 12, 2015, the entire contents of which are incorporated herein by reference.

### BACKGROUND

1. Field

The embodiments described below relate to a semiconductor memory device.

2. Description of the Related Art

In the field of a NAND flash memory, a stacked (three-dimensional) NAND flash memory has recently drawn attention as a device that can be highly integrated without being restricted by the resolution limit of the lithography technology. This kind of three-dimensional NAND flash memory includes an alternating stack of conductive films and interlayer dielectric films, the conductive films functioning as word-lines and select gate lines, and a semiconductor layer formed to pass through the stack. This semiconductor layer functions as the body of a memory string. The semiconductor layer and the conductive films have a memory film formed therebetween that includes a charge accumulation film.

### BRIEF DESCRIPTION OF THE DRAWINGS

FIG. 1 is a block diagram of a schematic configuration of a non-volatile semiconductor memory device according to a first embodiment.

FIG. 2 is a circuit diagram partially showing the configuration of the non-volatile semiconductor memory device.

FIG. 3 is a schematic perspective view partially showing the configuration of the non-volatile semiconductor memory device.

FIG. 4 is a schematic cross-sectional view partially showing the configuration of the non-volatile semiconductor memory device.

FIG. 5 is a schematic cross-sectional view partially showing the configuration of the non-volatile semiconductor memory device.

FIG. 6 is a schematic plan view partially showing the configuration of the non-volatile semiconductor memory device.

FIG. 7 is a schematic cross-sectional view partially showing the configuration of a non-volatile semiconductor memory device according to a second embodiment.

FIG. 8 is a schematic plan view partially showing the configuration of the non-volatile semiconductor memory device.

FIG. 9 is a schematic cross-sectional view partially showing a manufacturing process of the non-volatile semiconductor memory device.

### DETAILED DESCRIPTION

The semiconductor memory device according to the embodiments described below includes a plurality of memory blocks provided in a first direction. Each memory block includes a substrate, a plurality of conductive layers stacked on the substrate at a certain distance, and a plurality of semiconductor layers opposed to the conductive layers via an insulating layer and a charge accumulation layer. The semiconductor layers have a longitudinal direction in a direction perpendicular to the substrate. The conductive layers and the semiconductor layers are provided in the first direction. The distance between two memory blocks adjacent in the first direction is larger than the distance between the conductive layers adjacent in the first direction in each memory block.

Next, the semiconductor memory device according to the embodiments will be described in more detail with reference to the drawings.

### First Embodiment

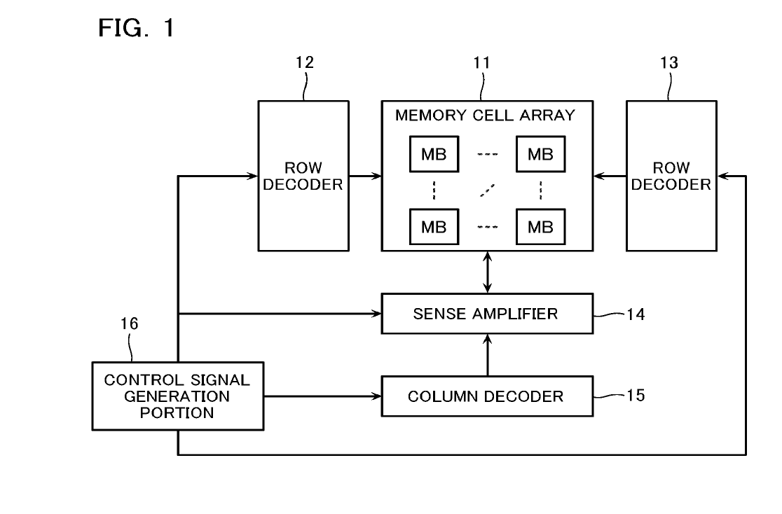

FIG. 1 is a block diagram of a non-volatile semiconductor memory device according to a first embodiment. The non-volatile semiconductor memory device according to the first embodiment includes, as shown in FIG. 1, a memory cell array 11, row decoders 12 and 13 that control the reading and writing of the memory cell array 11, a sense amplifier 14, a column decoder 15, and a control signal generation portion 16.

The memory cell array 11 includes a plurality of memory blocks MB. Each memory block MB includes a plurality of memory transistors MTr that store data in a non-volatile manner and are arranged three-dimensionally. Each memory block MB thus forms a minimum erase unit that is collectively erased in the data erase operation. The memory transistors MTr are arranged three-dimensionally in the row, column, and stacking directions.

The row decoders 12 and 13 decode, as shown in FIG. 1, a captured block address signal or the like and control the memory cell array 11. The sense amplifier 14 reads data from the memory cell array 11. The column decoder 15 decodes a column address signal and controls the sense amplifier 14. The control signal generation portion 16 increases the reference voltage to generate a high voltage necessary in the writing and erasing. The control signal generation portion 16 also generates a control signal to control the row decoders 12 and 13, the sense amplifier 14, and the column decoder 15. Note that the row decoders 12 and 13, the sense amplifier 14, the column decoder 15, and the control signal generation portion 16 form a control circuit that applies a voltage to the memory transistors MTr in the memory cell array.

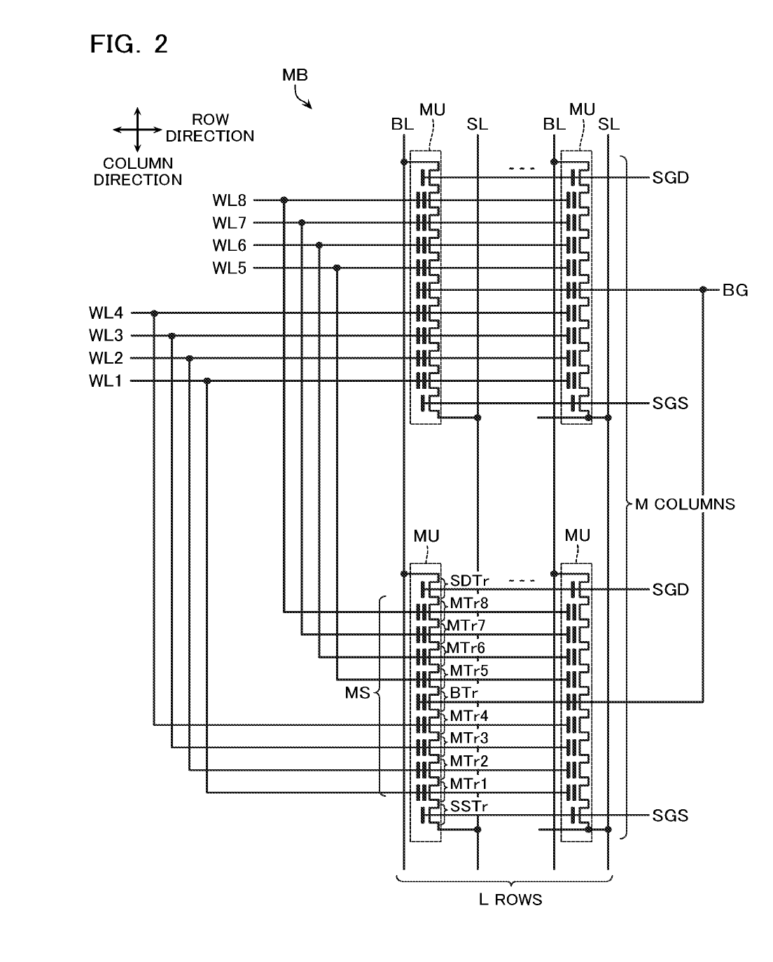

Next, with reference to FIG. 2, the specific configuration of the memory blocks MB will be described. FIG. 2 is a circuit diagram for illustrating the specific configuration of the memory blocks MB. Each memory block MB includes a plurality of bit-lines BL, a plurality of source-lines SL, and a plurality of memory units MU connected to the bit-lines BL and the source-lines SL.

Each memory unit MU forms a NAND flash memory. Each memory unit MU includes a memory string MS, the memory string MS including series-connected memory transistors MTr1 to MTr8 and a back gate transistor BTr, and a source-side select transistor SSTr and a drain-side select transistor SDTr that are connected to the respective ends of the memory string MS. The memory transistors MTr1 to MTr8 accumulate charges in their charge accumulation layers to change their threshold voltage and hold data corresponding to the threshold voltage.

The drain-side select transistors SDTr in the memory units MU arranged in the column direction have drains connected to a common bit-line BL. The source-side select transistors SSTr in the memory units MU arranged in the column direction have sources connected to a common source-line SL. The memory transistors MTr1 to MTr8 have gates connected to respective word-lines WL1 to WL8. The back gate transistors BTr have gates commonly connected to a back gate line BG. The source-side select transistors SSTr have gates connected to source-side select gate lines SGS. The drain-side select transistors SDTr have gates connected to drain-side select gate lines SGD.

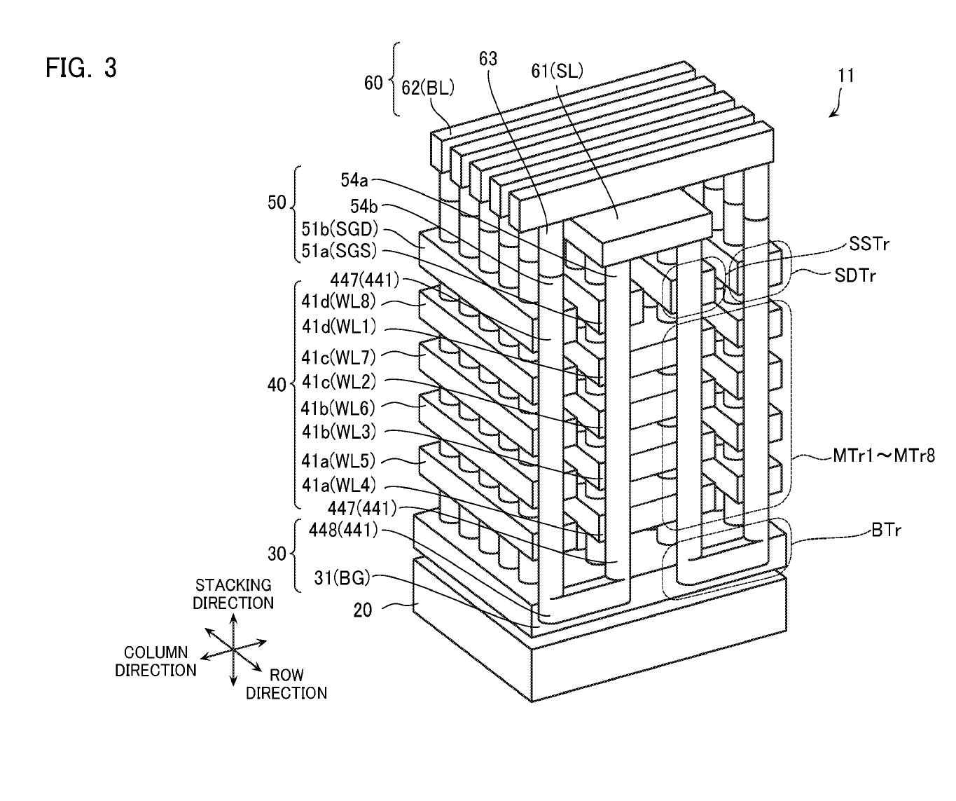

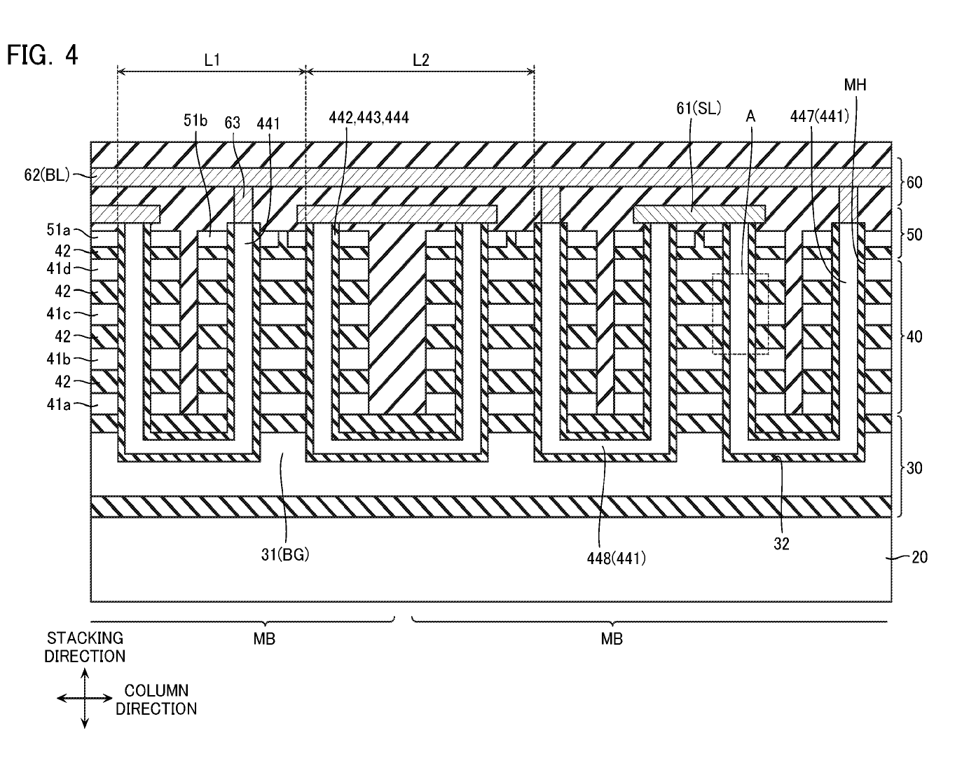

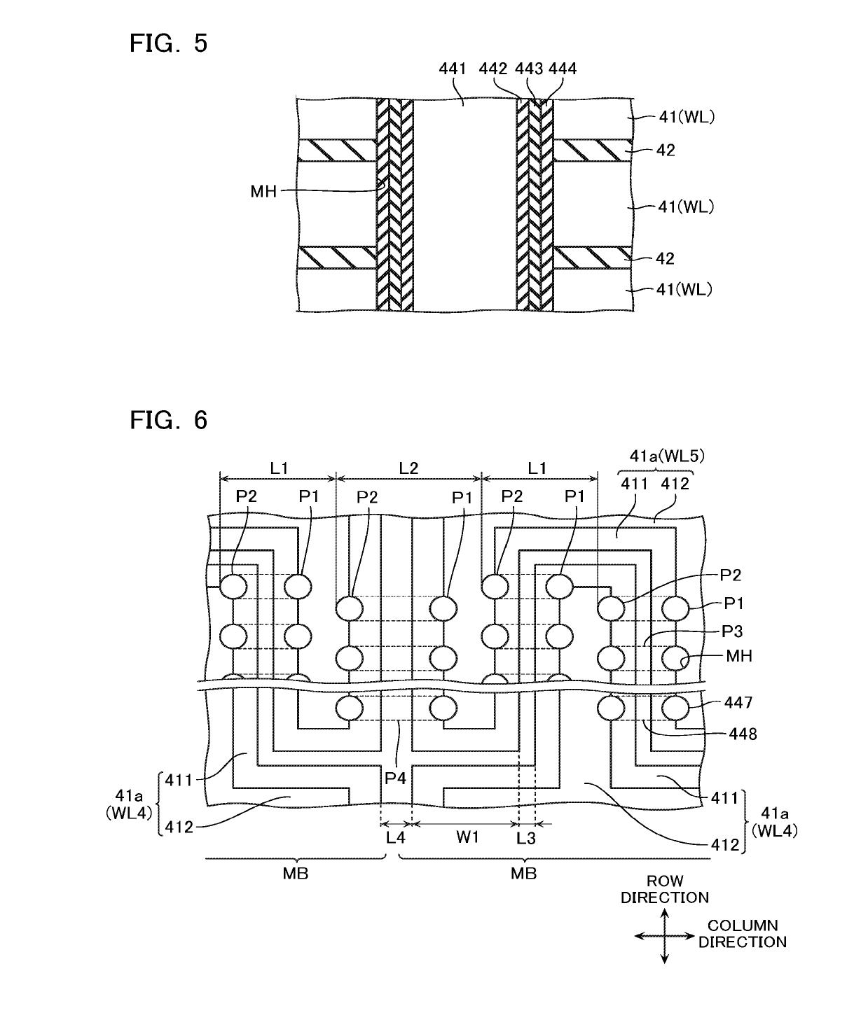

Next, with reference to FIGS. 3 to 5, the structure of the non-volatile semiconductor memory device according to the first embodiment will be described in more detail. FIG. 3 is a perspective view partially showing the memory cell array 11. FIG. 4 is a cross-sectional view partially showing the non-volatile semiconductor memory device. In addition, FIG. 5 is an enlarged view of the portion depicted by A in FIG. 4.

Note that although a description is given below with respect to a memory cell array 11 having a Silicon/Oxide/Nitride/Oxide/Silicon structure (SONOS structure), other memory cell arrays may also be used that include a Metal/Oxide/Nitride/Oxide/Silicon structure (MONOS structure) or a Floating Gate structure.

Each memory cell array 11 includes, as shown in FIGS. 3 and 4, a substrate 20, a back gate layer 30, a memory layer 40, a select transistor layer 50, and a wiring layer 60, which are sequentially stacked on the substrate 20. The back gate layer 30 functions as the back gate transistors BTr. The memory layer 40 functions as the memory transistors MTr1 to MTr8. The select transistor layer 50 functions as the drain-side select transistors SDTr and the source-side select transistors SSTr. The wiring layer 60 functions as the source-lines SL and the bit-lines BL.

The back gate layer 30 includes, as shown in FIG. 3, a back gate conductive layer 31. The back gate conductive layer 31 functions as the back gate lines BG and the gates of the back gate transistors BTr. The back gate conductive layer 31 is formed as a plate extending two-dimensionally in the row and column directions parallel to the substrate portion 20. The back gate conductive layer 31 is formed of, for example, a conductive layer such as polysilicon. The back gate conductive layer 31 may also be formed of, for example, metal such as tungsten.

The back gate layer 30 includes, as shown in FIG. 4, back gate holes 32. The back gate holes 32 are formed digging the back gate conductive layer 31.

The memory layer 40 is formed over, as shown in FIGS. 3 and 4, the back gate layer 30. The memory layer 40 includes a plurality of (fours in FIGS. 3 and 4) word-line conductive layers 41a to 41d. The word-line conductive layer 41a functions as the word-line WL4 and the gate of the memory transistor MTr4. The word-line conductive layer 41a also functions as the word-line WL5 and the gate of the memory transistor MTr5. Likewise, the word-line conductive layers 41b to 41d function as the word-lines WL1 to WL3 and WL6 to WL8 and the gates of the memory transistors MTr1 to MTr3 and MTr6 to MTr8. In addition, as shown in FIG. 4, an interlayer insulating layer 42 is formed over and under each word-line conductive layer 41.

Note that the word-line conductive layers 41a to 41d are formed of, for example, a conductive layer such as polysilicon. The word-line conductive layers 41a to 41d may also be formed of, for example, metal such as tungsten. In addition, the interlayer insulating layer 42 is formed of, for example, an insulating layer such as silicon oxide.

The memory layer 40 includes, as shown in FIG. 4, memory holes MH. The memory holes MH are formed passing though the word-line conductive layers 41a to 41d and the interlayer insulating layer 42. The memory holes MH are formed to be aligned to the vicinities of the column-direction end portions of the back gate holes 32.

In addition, as shown in FIG. 4, the back gate layer 30 and the memory layer 40 include a memory semiconductor layer 441. The memory semiconductor layer 441 functions as the bodies (channels) of the memory strings MS (the memory transistors MTr1 to MTr8) and the back gate transistors BTr.

Note that the memory semiconductor layer 441 is formed of, for example, a conductive layer such as polysilicon.

In addition, as shown in FIG. 5, each of the back gate layer 30 and the memory layer 40 includes a tunnel insulating layer 442 covering the memory semiconductor layer 441, a charge accumulation layer 443 covering the tunnel insulating layer 442, and a block insulating layer 444 covering the charge accumulation layer 443. The charge accumulation layer 443 is configured to be able to accumulate charges. Note that although in FIG. 5, the tunnel insulating layer 442, the charge accumulation layer 443, and the block insulating layer 444 surround the entire side surface of the memory semiconductor layer 441, they may only surround portions of the side surfaces of the memory semiconductor layer 441 that are opposed to the word-line conductive layers 41.

Note that the tunnel insulating layer 442 and the block insulating layer 444 are formed of, for example, an insulating layer such as silicon oxide. In addition, the charge accumulation layer 443 is formed of, for example, a material such as silicon nitride that may accumulate charges.

As shown in FIG. 4, the memory semiconductor layer 441, the tunnel insulating layer 442, the charge accumulation layer 443, and the block insulating layer 444 are formed filling in the back gate holes 32 and the memory holes MH. The memory semiconductor layer 441 includes a pair of columnar portions 447 extending perpendicularly to the substrate portion 20 and a coupling portion 448 coupling the pair of columnar portions 447 at their lower ends. The memory semiconductor layer 441 is formed in a U-shape when viewed in the row direction.

The above back gate layer 30 is formed surrounding the side surface of the coupling portion 448. In addition, the word-line conductive layers 41a to 41d are formed surrounding the side surface of each columnar portion 447.

In addition, as shown in FIG. 3, a first columnar portion 447 has an upper portion that is surrounded by a source-side conductive layer 51a that functions as the source-side select gate lines SGS. The upper portion functions as the channels of the source-side select transistors SSTr. Likewise, a second columnar portion 447 has an upper portion that is surrounded by a drain-side conductive layer 51b that functions as the drain-side select gate lines SGD. The upper portion functions as the channels of the drain-side select transistors SDTr.

In addition, as shown in FIG. 3, the first columnar portion 447 has an upper portion connected to a source-line layer 61 that functions as the source-lines SL. In addition, the second columnar portion 447 has an upper portion connected to, via a plug layer 63, a bit-line layer 62 that functions as the bit-lines BL.

The source-line layer 61, the bit-line layer 62, and the plug layer 63 are formed of, for example, electrically conductive layers such as polysilicon and tungsten.

Next, with reference to FIG. 6, the layout of the non-volatile semiconductor memory device according to this embodiment will be described. FIG. 6 is a schematic plan view of the word-line conductive layer 41a. Note that a description is given below with respect to the word-line conductive layer 41a, and the word-line conductive layers 41b to 41d are also formed similar to the word-line conductive layer 41a.

As shown in FIG. 6, a pair of word-line conductive layers 41a are provided in one memory block MB. The pair of word-line conductive layers 41a are formed in a comb teeth shape when viewed in a top plan view and are disposed to engage with each other in the row direction. Specifically, the word-line conductive layer 41a include a plurality of conductive layers 412 in the column direction, the conductive layers 412 extending in the row direction. In addition, the conductive layers 412 are commonly connected at the row-direction end portions. In addition, the conductive layers 412 included in a certain word-line conductive layer 41a are adjacent in the column direction with the conductive layers 412 included in another word-line conductive layer 41a. The column-direction widths W1 of the conductive layers 412 are basically all the same. In addition, as shown in FIG. 6, each word-line conductive layer 41a has, along its periphery, a low resistance portion 411 having a lower resistance than other portions. Note that as described above, the word-line conductive layer 41a is formed of, for example, polysilicon or the like. The low resistance portions 411 are formed by, for example, silicidation of polysilicon of the like.

In addition, as shown in FIG. 6, each word-line conductive layer 41a is provided with the memory holes MH. FIG. 6 shows an example where the memory holes MH are formed in the row direction along the first and second column-direction ends of each conductive layer 412. In addition, in one conductive layer 412, all memory holes MH have different row-direction positions.

Each memory hole MH has a columnar portion 447 provided therein. The columnar portions 447 formed in two different word-line conductive layers 41a are coupled by the coupling portion 448. Note that in this embodiment, the two columnar portions 447 included in different memory blocks MB are also coupled by the coupling portion 448.

In addition, assuming that each pair of columnar portions 447 coupled by the coupling portion 448 includes a first columnar portion P1 located on the right side in FIG. 6 and a second columnar portion P2 located on the left side, the first columnar portions P1 and the second columnar portions P2 are respectively spaced by a distance L1 in the column direction. In addition, between the memory blocks MB adjacent in the column direction, the distance between the first columnar portions P1 is a distance L2 larger than the distance L1. Likewise, between the memory blocks MB adjacent in the column direction, the distance between the second columnar portions P2 is also the distance L2 larger than the distance L1. In addition, assuming that P3 is a coupling portion 448 coupling the two columnar portions 447 in the same memory block MB and P4 is a coupling portion 448 coupling the two columnar portions 447 provided across different memory blocks MB, P4 has a column-direction width larger than the column-direction width of P3.

As shown in FIG. 6, the memory blocks MB adjacent in the column direction has a distance L4 therebetween larger than the space L3 between the conductive layers 412 in the same memory block MB. In other words, among the conductive layers 412 included in the memory blocks MB adjacent in the column direction, the nearest layers have the distance L4 therebetween larger than the space L3 between the conductive layers 412 in the same memory block MB.

Here, the distance between the wiring lines (the thickness of the insulating layer) is usually set according to the portion receiving the highest voltage. For example, in a semiconductor memory device having a configuration as described with reference to FIGS. 2 to 5, a potential difference between the word-line conductive layers 41a included in the same memory block MB (for example, a potential difference between the word-lines WL4 and WL5) is exceeded by a potential difference between the word-line conductive layers 41a included in different memory blocks MB (for example, a potential difference between the two word-lines WL5 adjacent in the column direction). Usually, in such a case, taking into account the potential difference between the word-line conductive layers 41a included in different memory blocks MB, the distance between the memory blocks MB adjacent in the column direction and the space between the conductive layers 412 in the same memory block MB are set the same.

In contrast, in this embodiment, taking into account the potential difference between the word-line conductive layers 41a included in the same memory block MB, the space L3 between the conductive layers 412 in the same memory block MB is set independently from the distance L4 between the memory blocks MB adjacent in the column direction. Therefore, the space L3 between the conductive layers 412 adjacent in the column direction in the same memory block MB is set smaller than the distance L4 between the memory blocks MB adjacent in the column direction. The semiconductor memory device may thus be made more compact while preventing the dielectric breakdown or the like between the wiring lines.

### Second Embodiment

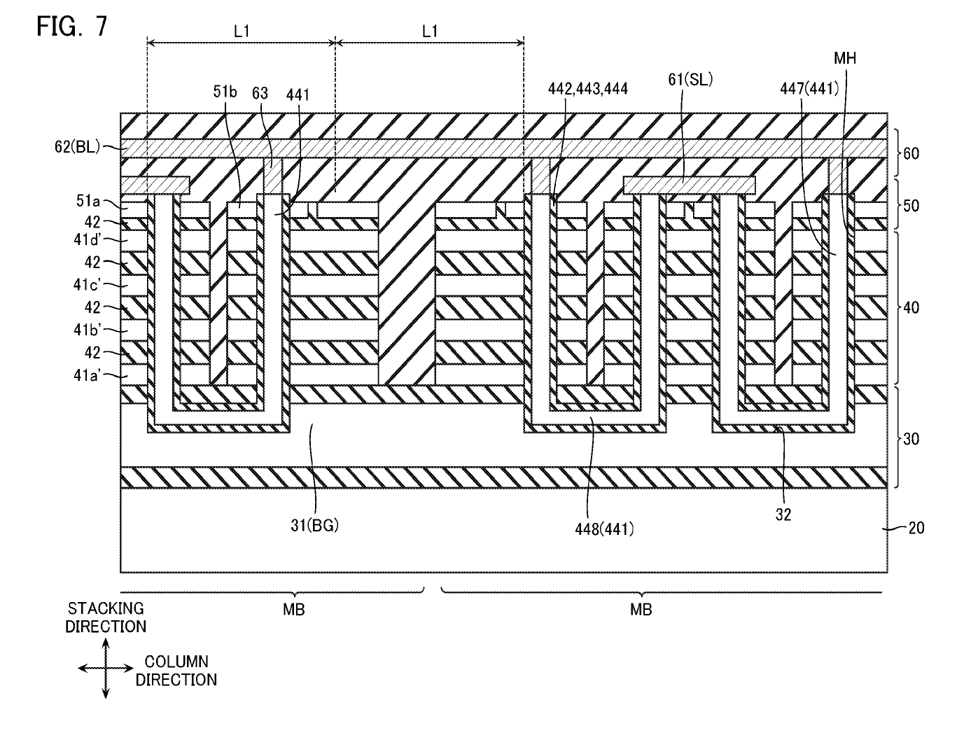

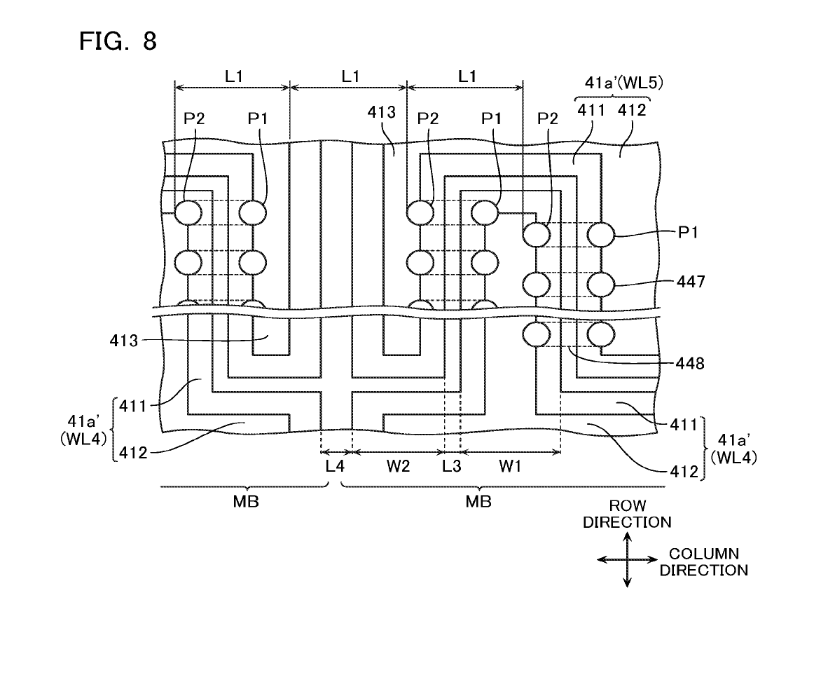

Next, with reference to FIGS. 7 and 8, a non-volatile semiconductor memory device according to a second embodiment will be described. FIG. 7 is a cross-sectional view partially showing the non-volatile semiconductor memory device according to this embodiment. FIG. 8 is a schematic plan view of a word-line conductive layer 41a′ according to this embodiment. Note that in the following discussion, like elements as those in the first embodiment are designated with like reference numerals and their description is omitted here.

As shown in FIGS. 7 and 8, in this embodiment, each word-line conductive layer 41a′ has a conductive layer 413 in the end portion thereof, and the conductive layer 413 has a column-direction width W2 smaller than the column-direction width W1 of other conductive layers 412.

In addition, as shown in FIG. 8, in this embodiment, the above conductive layer 413 has only one column of the memory holes MH formed therein. The columnar portions 447 in the memory holes MHs are coupled to the columnar portions 447 in the same memory block MB. Therefore, in this embodiment, the columnar portions 447 included in different memory blocks MB are not coupled.

In addition, assuming that each pair of columnar portions 447 coupled by the coupling portion 448 includes a first columnar portion P1 located on the right side in FIG. 8 and a second columnar portion P2 located on the left side, the first columnar portions P1 and the second columnar portions P2 are respectively spaced by a distance L1 in the column direction. In addition, between the memory blocks MB adjacent in the column direction, the distance between the first columnar portions P1 is an integral multiple of the distance L1. Likewise, between the memory blocks MB adjacent in the column direction, the distance between the second columnar portions P2 is also an integral multiple of the distance L1. In addition, between the memory blocks MB adjacent in the column direction, the distance between the first columnar portions P1 at the shortest distance is double the distance L1. In addition, between the memory blocks MB adjacent in the column direction, the distance between the second columnar portions P2 at the shortest distance is also double the distance L1.

As shown in FIG. 8, in this embodiment, each word-line conductive layer 41a′ has a conductive layer 413 in the end portion thereof, and the conductive layer 413 has a column-direction width W2 smaller than the column-direction width W1 of other conductive layers 412. Therefore, the semiconductor memory device may be made even more compact.

In addition, if, for example, the column-direction width W2 of the above conductive layer 413 is set smaller than the column-direction width W1 of other conductive layers 412 and two columns of the memory holes MH are formed in the conductive layer 413, one of the memory holes MH may narrow the low resistance portion 411, increasing the resistance of the word-line conductive layer 41a. In this regard, as shown in FIG. 8, in this embodiment, the above conductive layer 413 has only one column of the memory holes MH formed therein. This may thus prevent the memory holes MH from narrowing the low resistance portion 411 and the resulting increase of the resistance.

In addition, if, for example, the semiconductor memory device is to be made more compact, each configuration's column-direction width may be limited by the minimum processing dimension or the like. Therefore, it is preferable that the columnar portions 447 are arranged in the column direction at a certain distance or at an integral multiple of the certain distance.

Unfortunately, if, for example as shown by FIG. 6, the space L3 between the word-line conductive layers 41a in the same memory block MB is set smaller than the distance L4 between the memory blocks MB adjacent in the column direction, the distance L2 between the first columnar portions P1 between the memory blocks MB adjacent in the column direction may not be an integral multiple of the distance L1.

In this regard, in this embodiment, the distance between the first columnar portions P1 between the memory blocks MB adjacent in the column direction is set to an integral multiple of the distance L1. Likewise, the distance between the second columnar portions P2 between the memory blocks MB adjacent in the column direction is also an integral multiple of the distance L1. Therefore, taking into account the minimum processing dimension or the like, the column-direction space between the columnar portions 447 may be adjusted to make the semiconductor memory device more compact.

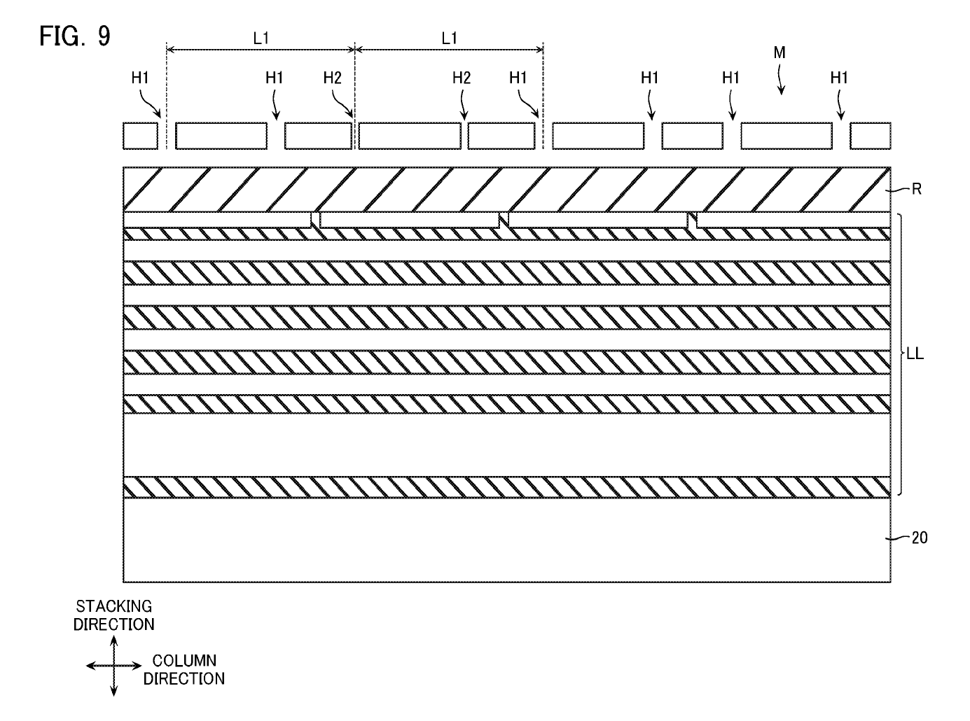

In addition, the semiconductor memory device according to this embodiment may also be manufactured as follows. FIG. 9 is a schematic cross-sectional view partially showing a manufacturing process of the semiconductor memory device according to this embodiment. FIG. 9 shows formation of the memory holes MH with lithography.

FIG. 9 shows an example where the substrate 20 has a stack LL formed thereon, the stack LL forming each layer of the semiconductor memory device according to this embodiment. In addition, the stack LL has a resist R applied thereon. In addition, the resist R has a mask M installed thereon.

In portions of the mask M where the memory holes MH (see FIG. 7) are formed, through-holes H1 are formed. In addition, in regions of the mask M between the memory block MBs, through-holes H2 are formed. Each through-hole H2 has a diameter small enough not to be resolved by the lithography system. In addition, a portion of the through-holes H1 that corresponds to the memory holes MH having the first columnar portions P1 and some of the through-holes H2 are formed in the column direction at the distance L1. Likewise, a portion of the through-holes H1 that corresponds to the memory holes MH having the second columnar portions P2 and the other through-holes H2 are formed in the column direction at the distance L1.

The mask M shown in FIG. 9 may be used to remove the resist R to form the memory holes MH, thus manufacturing the semiconductor memory device according to this embodiment more accurately.

### Other Embodiments

As described with reference to FIG. 3 or the like, the first and second embodiments include the U-shape memory semiconductor layer 441, the layer 441 including the pair of columns 447 and the coupling portion 448 connected to the lower ends thereof. An I-shape memory semiconductor layer may also be used, for example, the layer electrically connecting the upper ends of the columnar semiconductor layers to the respective bit-lines BL and electrically connecting the lower ends to the substrate or the like. In such a case, for example, conductive layers may be stacked on the substrate at a certain distance to provide the word-lines and the control gates of the memory transistors. In addition, a plurality of memory holes may be formed in the conductive layers and then the memory holes may be provided with the block insulating layers, the charge accumulation layers, the tunnel insulating layers, and the semiconductor layers to provide the charge accumulation layers and the channels of the memory transistors. In addition, a plurality of conductive layers may be stacked in the column direction, and the conductive layers as well as the charge accumulation layers and the semiconductor layers provided in the memory holes provided in the conductive layers may form the memory blocks. In addition, the memory blocks may be provided in the column direction and the column-direction distance between the memory blocks adjacent in the column direction may be set larger than the column-direction distance of the conductive layers included in each memory block. In addition, the semiconductor layers may be spaced by a first distance in the column direction in each memory block and the column-direction distance between the semiconductor layers in two memory blocks adjacent in the column direction may be set to an integral multiple of the first distance. In addition, between the adjacent memory blocks, the distance between the semiconductor layers at the shortest distance may be set to double the first distance.

### OTHERS

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising,
a plurality of memory blocks provided in a first direction,
one of the memory blocks comprising,
a plurality of conductive layers stacked at a certain distance in a stacking direction and provided in the first direction, and
a plurality of semiconductor layers opposed to the conductive layers via an insulating layer, the semiconductor layers having a longitudinal direction in the stacking direction and being provided in the first direction,
the distance between two memory blocks adjacent in the first direction being larger than the distance between the conductive layers adjacent in the first direction in one memory block.

2. The semiconductor memory device according to claim 1, wherein
the semiconductor layers are spaced by a first distance in the first direction in one memory block,
a first-direction distance between the semiconductor layers in the two adjacent memory blocks is an integral multiple of the first distance.

3. The semiconductor memory device according to claim 2, wherein
in the adjacent memory blocks, the distance between the semiconductor layers at the shortest distance is double the first distance.

4. The semiconductor memory device according to claim 1, wherein
an end portion of the conductive layers in the first direction have an electrical resistance value smaller than an electrical resistance value of a central portion of the conductive layers in the first direction.

5. The semiconductor memory device according to claim 1, wherein
an end portion of the conductive layers in the first direction are silicided.

6. The semiconductor memory device according to claim 1, wherein
one memory block further comprises a connecting portion connecting one ends of a pair of semiconductor layers respectively opposed to the two conductive layers adjacent in the first direction.

7. The semiconductor memory device according to claim 6, wherein
a plurality of pairs of semiconductor layers are provided,
first semiconductor layers of the pairs of semiconductor layers connected by the connecting portions are spaced by a first distance in the first direction in one memory block,
a distance in the first direction between the first semiconductor layers provided across the adjacent memory blocks is an integral multiple of the first distance,
second semiconductor layers of the pairs of semiconductor layers connected by the connecting portions are spaced by the first distance in the first direction in one memory block, and
a distance in the first direction between the second semiconductor layers in the adjacent memory blocks is an integral multiple of the first distance.

8. The semiconductor memory device according to claim 1, wherein
the semiconductor layers are spaced by a first distance in the first direction in one memory block, and
distance in the first direction between the semiconductor layers provided across the two adjacent memory blocks is larger than the first distance.

9. The semiconductor memory device according to claim 1, wherein
among the conductive layers, conductive layers in end portions of the memory blocks in the first direction have a width in the first direction smaller than a width in the first direction of other conductive layers among the conductive layers.

10. The semiconductor memory device according to claim 6, wherein
the connecting portion is provided in a plurality,
with a first connecting portion being a connecting portion connecting a pair of columnar portions provided in the same memory block and a second connecting portion being a connecting portion connecting a pair of columnar portions provided across the two adjacent memory blocks, the second connecting portion has a width in the first direction larger than a width in the first direction of the first connecting portion.
